(19) United States
(12) Patent Application Publication
(10) Pub. No.: US 2025/0268092 A1
(43) Pub. Date: Aug. 21, 2025

(54) DISPLAY DEVICE

(71) Applicant: LG Display Co., Ltd., Seoul (KR)

(72) Inventors: Yoonseob JEONG, Incheon (KR); JunHee ` HAN, Gimpo-si (KR)

(73) Assignee: LG Display Co., Ltd., Seoul (KR)

(21) Appl. No.: 18/967,228

(22) Filed: Dec. 3, 2024

(30) Foreign Application Priority Data
Feb. 19, 2024 (KR) 10-2024-0023288

(51) Int. Cl. H10K 71/00; H10K 59/12; H10K 59/131; H10K 59/80

(52) U.S. Cl. CPC H10K 71/861; H10K 59/1201; H10K 59/131; H10K 59/80

(57) ABSTRACT

A display device can include a substrate having an emission area and a non-emission area, at least one transistor disposed on the substrate and overlapping the emission area, a line disposed on the substrate and connected to the at least one transistor, at least one light emitting diode disposed on the at least one transistor and having a first electrode, a light-emitting layer, and a second electrode, and an optical member disposed on the at least one light emitting diode and overlapping the non-emission area.

### CROSS-REFERENCE TO RELATED APPLICATIONS

This application claims priority to Korean Patent Application No. 10-2024-0023288 filed on Feb. 19, 2024, in the Korean Intellectual Property Office, the entire disclosure of which is hereby expressly incorporated by reference into the present application.

### BACKGROUND

### Technical Field

The present disclosure relates to a display device, and more particularly, to a display device capable of stably performing a repair process while implementing a high aperture ratio.

### Discussion of the Related Art

Recently, display devices, which visually display electrical information signals, are being rapidly developed in accordance with the full-fledged entry into the information era. Various studies are being continuously conducted to develop a variety of display devices which are thin and lightweight, consume low power, and have improved performance.

As the representative display devices, there can be a liquid crystal display device (LCD), a field emission display device (FED), an electrowetting display device (EWD), an organic light-emitting display device (OLED), and the like.

Among the display devices, an organic light-emitting display device refers to a display device that autonomously emits light. Unlike a liquid crystal display apparatus, the organic light-emitting display device does not need a separate light source and thus can be manufactured as a lightweight, thin display device.

In addition, the organic light-emitting display device is advantageous in terms of power consumption because the electroluminescent display device operates at a low voltage. Further, the organic light-emitting display device is expected to be adopted in various fields because the organic light-emitting display device is also excellent in implementation of colors, response speeds, viewing angles, and contrast ratios (CRs).

### SUMMARY OF THE DISCLOSURE

An object to be achieved by the present disclosure is to provide a display device capable of repairing a defective subpixel without a loss of an aperture ratio.

Another object to be achieved by the present disclosure is to provide a display device capable of repairing a defective subpixel by cutting lines disposed in repair areas at various positions.

Objects of the present disclosure are not limited to the above-mentioned objects, and other objects, which are not mentioned above, can be clearly understood by those skilled in the art from the following descriptions.

According to an aspect of the present disclosure, there is provided a display device. The display device comprises a substrate comprising an emission area and a non-emission area, at least one transistor disposed on the substrate and disposed to overlap the emission area, a line disposed on the substrate and connected to the at least one transistor, at least one light emitting diode disposed on the at least one transistor and comprising a first electrode, a light-emitting layer, and a second electrode, and an optical member disposed on the at least one light emitting diode and disposed to overlap the non-emission area.

Other detailed matters of the example embodiments are included in the detailed description and the drawings.

According to the embodiments of the present disclosure, a defective subpixel is repaired by using an optical member disposed below a color filter, which can ensure the maximum aperture ratio of the subpixel.

According to the embodiments of the present disclosure, a defective subpixel can be repaired by cutting lines disposed in repair areas at various positions by using the grating member disposed between the optical member and the repair area.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a block diagram of a display device according to an embodiment of the present disclosure;

FIG. 2 is a circuit diagram illustrating an example of a subpixel circuit included in the display device in FIG. 1;

FIG. 3 is an enlarged top plan view of the display device according to the embodiment of the present disclosure;

FIG. 4 is a cross-sectional view illustrating an example cut along line I-I′ in FIG. 3;

FIG. 5 is a cross-sectional view illustrating an example cut along line II-II′ in FIG. 3;

FIGS. 6A and 6B are views for explaining an example of an optical member included in the display device in FIG. 3;

FIG. 7 is an enlarged top plan view of a display device according to another embodiment of the present disclosure;

FIG. 8 is a cross-sectional view illustrating an example cut along line III-III′ in FIG. 7;

FIGS. 9A and 9B are views for explaining an example of a grating member included in the display device in FIG. 7;

FIG. 10 is a cross-sectional view illustrating another example cut along line III-III′ in FIG. 7;

FIG. 11 is a cross-sectional view illustrating still another example cut along line III-III′ in FIG. 7; and

FIG. 12 is a cross-sectional view illustrating yet another example cut along line III-III′ in FIG. 7.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next to”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components and may not define order or sequence. Therefore, a first component to be mentioned below can be a second component in a technical concept of the present disclosure.

Like reference numerals generally denote like elements throughout the disclosure. Further, term “can” fully encompasses all the meanings and coverages of the term “may.”

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings. All the components of each display device according to all embodiments of the present disclosure are operatively coupled and configured.

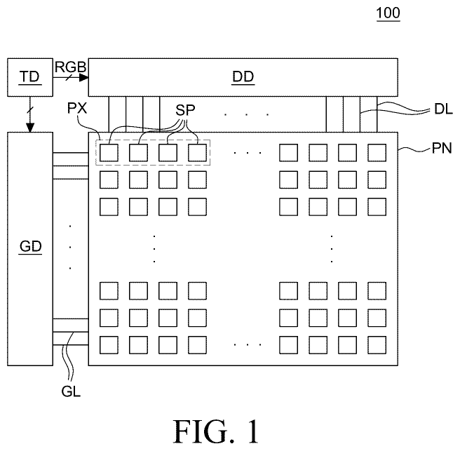

FIG. 1 is a block diagram of a display device according to an embodiment of the present disclosure.

An electroluminescent display device can be applied as the display device according to the embodiment of the present disclosure. An organic light-emitting diode display device, a quantum-dot light-emitting diode display device, or an inorganic light-emitting diode display device can be used as the electroluminescent display device.

With reference to FIG. 1, a display device 100 can include a display panel PN, a gate driver GD, a data driver DD, and a timing controller TD.

The display panel PN can create an image to be provided to the user. The display panel PN can include a display area and a non-display area configured to surround the display area.

The display area of the display panel PN can include the plurality of pixels PX disposed in the row direction and the column direction. For example, the plurality of pixels PX can be disposed in an area in which a plurality of data lines DL and a plurality of gate lines GL intersect.

The non-display area of the display panel PN can be disposed along a periphery of the display area. Various constituent elements for operating the pixel circuit disposed in the pixel PX can be disposed in the non-display area. For example, various types of signal lines, pads, at least a part of the gate driver GD, and the like can be disposed in the non-display area. The non-display area can be referred to as a bezel area.

The display panel PN can be implemented as a display panel used for various display devices. Hereinafter, the configuration will be described in which the display panel PN is a panel used for an organic light-emitting display device. However, the present disclosure is not limited thereto.

The data driver DD, the gate driver GD, and the timing controller TD can provide signals for operating the pixels PX through signal lines. For example, the signal lines for providing the signals for operating the pixels PX can include the plurality of data lines DL and the plurality of gate lines GL.

The plurality of data lines DL can include a plurality of lines arranged in a column direction and connected to the pixels PX disposed in one column direction. The plurality of gate lines GL can include a plurality of lines arranged in a row direction and connected to the pixels PX disposed in one row direction.

In some instances, the display device 100 can further include a power source unit. In this case, the signal for operating the pixel PX can be provided through a power line that connects the power source unit and the display panel PN. According to the embodiment, the power source unit can provide power to the data driver DD and the gate driver GD. The data driver DD and the gate driver GD can operate on the basis of power provided from the power source unit.

The timing controller TD can control the data driver DD and the gate driver GD. For example, the timing controller TD can realign digital video data, which are inputted from the outside, to fit the resolution of the display panel PN and supply the video data to the data driver DD. In addition, the timing controller TD can generate timing control signals for controlling the data driver DD and the gate driver GD by using a control signal inputted from the outside and provide the timing control signals to the data driver DD and the gate driver GD.

The data driver DD can convert digital video data, which are inputted from the timing controller TD, into analog data voltage on the basis of a data control signal and supply the analog data voltage to the plurality of data lines DL.

The gate driver GD can generate a gate signal on the basis of a gate control signal. For example, the gate driver GD can generate gate signals in a row-sequential manner to operate at least one gate line connected to each pixel row and supply the gate signals to the gate lines.

According to the embodiment, the gate driver GD can be disposed on the display panel PN in a gate-driver-in-panel (GIP) manner. For example, the gate driver GD can be divided into a plurality of gate drivers and respectively disposed on at least two side surface of the display panel PN. However, the present disclosure is not limited thereto.

The plurality of pixels PX included in the display panel PN can each include a plurality of subpixels SP. The plurality of subpixels SP included in one pixel PX can emit light beams with different colors. For example, the plurality of subpixels SP included in one pixel PX can include a first subpixel configured to emit red light, a second subpixel configured to emit white light, a third subpixel configured to emit blue light, and a fourth subpixel configured to emit green light. However, the present disclosure is not limited thereto. The plurality of subpixels SP can constitute the pixel PX.

Meanwhile, in the present disclosure, the first subpixel can be referred to as a red subpixel, the second subpixel can be referred to as a white subpixel, the third subpixel can be referred to as a blue subpixel, and the fourth subpixel can be referred to as a green subpixel.

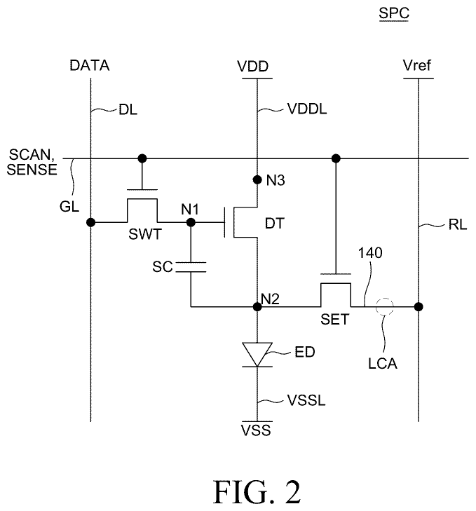

Hereinafter, a subpixel circuit for operating one subpixel SP will be described in more detail with reference to FIG. 2.

FIG. 2 is a circuit diagram illustrating an example of the subpixel circuit included in the display device in FIG. 1.

Meanwhile, a subpixel circuit SPC illustrated in FIG. 2 is an embodiment of a subpixel circuit corresponding to each of the plurality of subpixels SP included in the display device 100 described with reference to FIG. 1.

With reference to FIG. 2, the subpixel circuit SPC can include a driving transistor DT, a switching transistor SWT, a sensing transistor SET, a storage capacitor SC, and a light emitting diode ED.

The light emitting diode ED can include a first electrode, a light-emitting layer, and a second electrode. For example, the first electrode of the light emitting diode ED is an anode electrode and can be connected to a second node N2 corresponding to a second electrode of the driving transistor DT. For example, the second electrode of the light emitting diode ED is a cathode electrode and can be connected to a low-potential power line VSSL configured to supply a low-potential power voltage VSS. For example, the light-emitting layer of the light emitting diode ED is an organic layer and can include various organic layers such as a hole injection layer, a hole transport layer, an organic light-emitting layer, an electron transport layer, and an electron injection layer. Meanwhile, FIG. 2 illustrates that the light emitting diode ED is an organic light emitting diode. However, the present disclosure is not limited thereto. An inorganic light-emitting diode can also be used as the light emitting diode ED.

The driving transistor DT can supply a drive current from a high-potential power line VDDL configured to supply a high-potential power voltage VDD so that the drive current passes through the light emitting diode ED and flows to the low-potential power line VSSL configured to supply the low-potential power voltage VSS. The light emitting diode ED can emit light on the basis of the drive current supplied from the driving transistor DT.

The driving transistor DT can include a gate electrode connected between the second node N2 and a third node N3 and connected to a first node N1. For example, the driving transistor DT can include a first electrode connected to the third node N3, and the second electrode connected to the second node N2.

The switching transistor SWT can provide a data voltage DATA, which is provided from the data line DL, to the first node N1 corresponding to the gate electrode of the driving transistor DT.

The switching transistor SWT can include a gate electrode connected between the data line DL and the first node N1 and connected to a gate line GL. For example, the switching transistor SWT can include a first electrode connected to the data line DL, and a second electrode connected to the first node N1. The switching transistor SWT can be turned on or off by a scan signal SCAN supplied through the gate line GL. Therefore, the switching transistor SWT can be turned on in case that the scan signal SCAN with a turn-on level is supplied to the gate line GL, and the switching transistor SWT can transmit the data voltage DATA, which is supplied through the data line DL, to the first node N1 corresponding to the gate electrode of the driving transistor DT.

The storage capacitor SC can maintain a voltage corresponding to the data voltage DATA for one frame. The storage capacitor SC can be connected between the first node N1 and the second node N2 respectively corresponding to the gate electrode and the second electrode of the driving transistor DT. For example, one electrode of the storage capacitor SC can be connected to the first node N1. The other electrode of the storage capacitor SC can be connected to the second node N2.

Meanwhile, in the case of the display device 100, the circuit element such as the driving transistor DT can be degraded as the operating time of each of the subpixels SP increases. Therefore, an inherent characteristic value of the circuit element such as the driving transistor DT can change. In this case, the inherent characteristic values of the circuit element can include the threshold voltage Vth of the driving transistor DT, mobility α of the driving transistor DT, and the like. A change in characteristic value of the circuit element can cause a change in luminance of the corresponding subpixel SP. Therefore, the change in characteristic value of the circuit element can be used as the same concept as the change in luminance of the subpixel SP.

In addition, a degree of the change in characteristic values between the circuit elements of each of the subpixels SP can vary depending on a difference in degree of degradation between the circuit elements. A difference in degree of change in characteristic values between the circuit elements can cause a luminance deviation between the subpixels SP. Therefore, the deviation of characteristic values between the circuit element can be used as the same concept as the luminance deviation between the subpixels SP. The change in characteristic value of the circuit element, i.e., the deviation between the change in luminance of the subpixel SP and the characteristic values between the circuit elements, i.e., the luminance deviation between the subpixels SP can cause problems such as accuracy deterioration of luminance expression of the subpixel SP or screen abnormality.

Therefore, a sensing function of sensing the characteristic values of the subpixels SP and a compensation function of compensating for the characteristic value of the subpixel SP by using the sensing result can be provided to the subpixels SP of the display device 100 according to the embodiment of the present disclosure.

Therefore, identical to the switching transistor SWT, the driving transistor DT, the storage capacitor SC, and the light emitting diode ED, the subpixel SP can further include the sensing transistor SET for effectively controlling a voltage state of the second electrode of the driving transistor DT.

With reference to FIG. 2, the sensing transistor SET can include a gate electrode connected between the second node N2 and a reference voltage line RL configured to supply a reference voltage Vref, and the gate electrode being connected to the gate line GL configured to supply a sensing signal SENSE. For example, the sensing transistor SET can include a first electrode connected to the reference voltage line RL through a reference voltage connection line 140, and a second electrode connected to the second node N2 corresponding to the second electrode of the driving transistor DT. The sensing transistor SET can be turned on or off by the sensing signal SENSE supplied through the gate line GL. Therefore, the sensing transistor SET can be turned on in case that the sensing signal SENSE with a turn-on level is supplied to the gate line GL, and the sensing transistor SET can transmit the reference voltage Vref, which is supplied through the reference voltage line RL, to the second node N2 corresponding to the second electrode of the driving transistor DT.

In addition, the sensing transistor SET can be used as one of the voltage sensing paths for the second electrode of the driving transistor DT.

With reference to FIG. 2, the switching transistor SWT and the sensing transistor SET of the subpixel SP can share the single gate line GL. For example, the switching transistor SWT and the sensing transistor SET can be connected to the same gate line GL and receive the same gate signal. However, for the convenience of description, the voltage applied to the gate electrode of the switching transistor SWT is referred to as the scan signal SCAN, the voltage applied to the gate electrode of the sensing transistor SET is referred to as the sensing signal SENSE. However, the scan signal SCAN and the sensing signal SENSE, which are applied to the single subpixel SP, can be identical signals transmitted from the same gate line GL. For example, the scan signal SCAN and the sensing signal SENSE applied to one subpixel SP can be referred to as gate signals.

However, the present disclosure is not limited thereto. Only the switching transistor SWT can be connected to the gate line GL configured to supply the scan signal SCAN, and the sensing transistor SET can be connected to a separate sensing line configured to supply the sensing signal SENSE.

Therefore, the reference voltage Vref can be applied to the second electrode of the driving transistor DT through the sensing transistor SET. In addition, the voltage for sensing the threshold voltage Vth of the driving transistor DT or the mobility α of the driving transistor DT can be detected by the reference voltage line RL. Further, the data driver DD can compensate for the data voltage DATA depending on the amount of detected change in threshold voltage Vth of the driving transistor DT or the amount of detected change in mobility α of the driving transistor DT.

According to the embodiment, the plurality of transistors DT, SWT, and SET in FIG. 2 can include at least one of oxide semiconductors such as amorphous silicon, polycrystalline silicon, and IGZO. The first or second electrode of the transistor can be a source electrode or a drain electrode. For example, the first electrode can be a source electrode, or the second electrode can be a drain electrode. As another example, the first electrode can be a drain electrode, and the second electrode can be a source electrode.

Meanwhile, in the display device 100 according to the embodiment of the present disclosure, in case that some of the plurality of subpixels SP are defective, the reference voltage connection line 140 disposed in a repair area LCA can be cut by a laser. When the reference voltage connection line 140 of the defective subpixel SP is cut as described above, the sensing transistor is electrically separated from the reference voltage line RL configured to provide the reference voltage Vref, such that the reference voltage Vref supplied through the reference voltage line RL is not supplied to the sensing transistor SET. Therefore, because the driving transistor DT cannot be supplied with the reference voltage Vref from the sensing transistor SET, the driving transistor DT does not operate, and as a result, the light emitting diode ED cannot emit light. For example, the subpixel SP including a defective circuit element can become a dark spot by the repair process.

However, the repair area LCA, which is subjected to the laser cutting, is not limited thereto. The repair area LCA can be variously set. For example, the repair area LCA can be set on various lines, such as the data line DL configured to supply the data voltage DATA or the connection line configured to connect the driving transistor DT and the light emitting diode ED, in such a case that the driving transistor DT does not operate and/or the light emitting diode ED does not emit light when the corresponding line is cut by a laser. Hereinafter, for convenience of description, a configuration in which the repair area LCA is set on the reference voltage connection line 140 will be described.

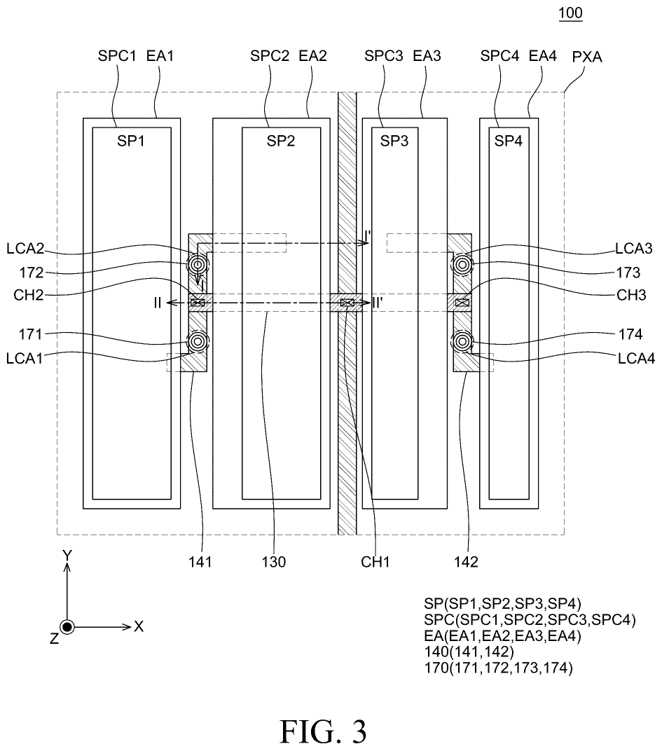

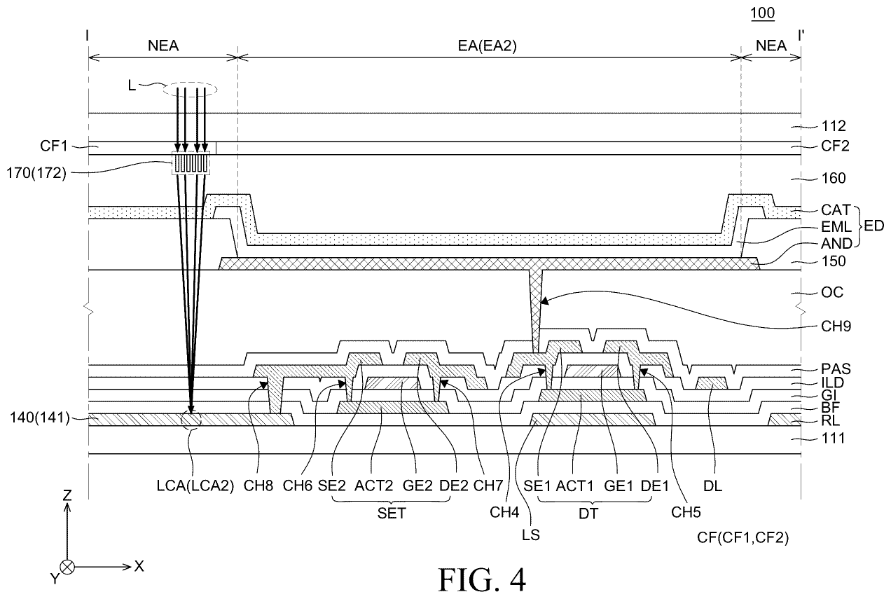

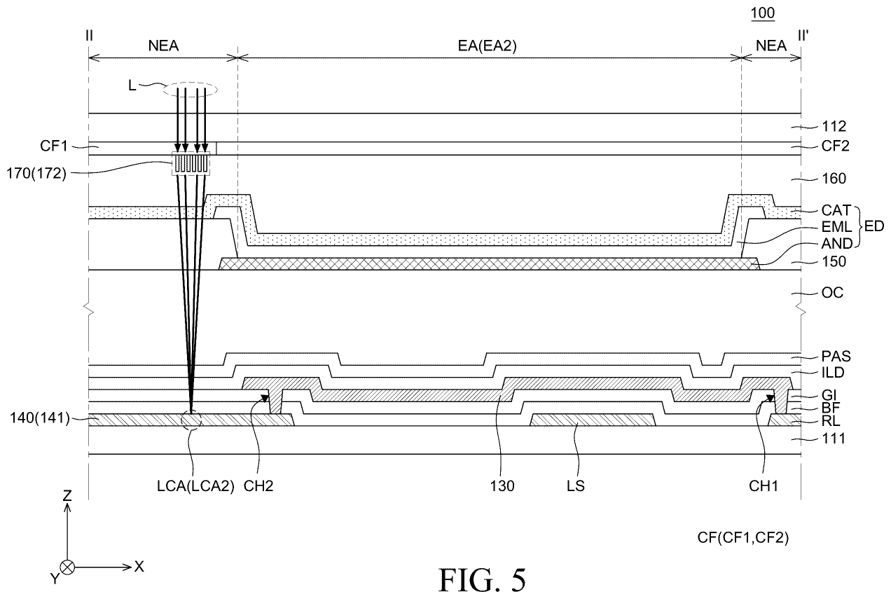

FIG. 3 is an enlarged top plan view of the display device according to the embodiment of the present disclosure. FIG. 4 is a cross-sectional view illustrating an example cut along line I-I′ in FIG. 3. FIG. 5 is a cross-sectional view illustrating an example cut along line II-II′ in FIG. 3.

Meanwhile, for convenience of description, hereinafter, a first direction X is illustrated as a horizontal direction in a plan view, and a second direction Y is illustrated as a vertical direction in a plan view. In addition, a normal direction to a plane defined by the first direction X and the second direction Y, e.g., a thickness direction of the display device 100 can be defined as a third direction Z.

Particularly, FIGS. 4 and 5 illustrate examples of cross-sectional structures of the display device 100 according to the embodiment of the present disclosure.

With reference to FIG. 3, the display device 100 according to the embodiment of the present disclosure can include the plurality of subpixels SP disposed in one pixel area PXA and each including the corresponding subpixel circuit SPC.

The plurality of subpixels SP can include a first subpixel SP1 configured to emit red light and including a first subpixel circuit SPC1, a second subpixel SP2 configured to emit white light and including a second subpixel circuit SPC2, a third subpixel SP3 configured to emit blue light and including a third subpixel circuit SPC3, and a fourth subpixel SP4 configured to emit green light and including a fourth subpixel circuit SPC4.

The plurality of subpixels SP disposed in one pixel area PXA can be sequentially disposed in the first direction X. For example, the second subpixel SP2 can be disposed at one side of the first subpixel SP1 based on the first direction X, the third subpixel SP3 can be disposed at one side of the second subpixel SP2 based on the first direction X, and the fourth subpixel SP4 can be disposed at one side of the third subpixel SP3 based on the first direction X. However, the present disclosure is not limited thereto. The arrangements of the subpixels SP can be variously modified and carried out.

The plurality of subpixels SP can each include an emission area EA. For example, the first subpixel SP1 can include a first emission area EA1, the second subpixel SP2 can include a second emission area EA2, the third subpixel SP3 can include a third emission area EA3, and the fourth subpixel SP4 can include a fourth emission area EA4.

The emission area EA included in each of the plurality of subpixels SP is an area that can independently emit light with a single type of color. The light emitting diode ED corresponding to the corresponding subpixel SP can be disposed in the emission area EA. For example, red light can be emitted from the first emission area EA1, white light can be emitted from the second emission area EA2, blue light can be emitted from the third emission area EA3, and green light can be emitted from the fourth emission area EA4.

The subpixel circuits SPC respectively included in the plurality of subpixels SP can have substantially identical or similar structures, and the plurality of subpixels SP disposed in one pixel area PXA can share at least one signal line. For example, as illustrated in FIG. 3, the first subpixel SP1, the second subpixel SP2, the third subpixel SP3, and the fourth subpixel SP4 disposed in one pixel area PXA can share one reference voltage line RL.

Meanwhile, although not illustrated in FIG. 3, at least some of the plurality of subpixels SP disposed in one pixel area PXA can share the high-potential power line VDDL that is provided with the high-potential power voltage VDD and extends in the second direction Y. However, the present disclosure is not limited thereto.

The reference voltage line RL configured to supply the reference voltage Vref can be disposed between the plurality of subpixels SP. For example, the reference voltage line RL can be disposed between the second subpixel SP2 and the third subpixel SP3 and extend in the second direction Y.

In addition, a connection line 130, which is disposed to traverse the corresponding pixel area PXA in the first direction X, can be connected to the reference voltage line RL. For example, the connection line 130 can extend in the first direction X to traverse the first subpixel SP1, the second subpixel SP2, the third subpixel SP3, and the fourth subpixel SP4, and a central portion of the connection line 130 can be connected to the reference voltage line RL through a first contact hole CH1.

In addition, the reference voltage connection line 140 disposed between the plurality of subpixels SP can be connected to the connection line 130. For example, the reference voltage line 140 can include a first reference voltage connection connection line 141 disposed between the first subpixel SP1 and the second subpixel SP2, and a second reference voltage connection line 142 disposed between the third subpixel SP3 and the fourth subpixel SP4.

The first reference voltage connection line 141 can include a first main portion extending in the second direction Y, and the first main portion of the first reference voltage connection line 141 and the connection line 130 can be connected through a second contact hole CH2 in a central portion of the first main portion of the first reference voltage connection line 141. In addition, the first reference voltage connection line 141 can include a first auxiliary portion extending from one end of the first main portion in a direction opposite to the first direction X and connected to the first subpixel circuit SPC1, and a second auxiliary portion extending from the other end of the first main portion in the first direction X and connected to the second subpixel circuit SPC2. Therefore, the reference voltage Vref can be supplied to the first subpixel circuit SPC1 and the second subpixel circuit SPC2 through the first reference voltage connection line 141 connected to the reference voltage line RL through the connection line 130.

In addition, the second reference voltage connection line 142 can include a second main portion extending in the second direction Y, and the second main portion of the second reference voltage connection line 142 and the connection line 130 can be connected through a third contact hole CH3 in a central portion of the second main portion of the second reference voltage connection line 142. In addition, the second reference voltage connection line 142 can include a third auxiliary portion extending from one end of the second main portion in a direction opposite to the first direction X and connected to the third subpixel circuit SPC3, and a fourth auxiliary portion extending from the other end of the second main portion in the first direction X and connected to the fourth subpixel circuit SPC4. Therefore, the reference voltage Vref can be supplied to the third subpixel circuit SPC3 and the fourth subpixel circuit SPC4 through the second reference voltage connection line 142 connected to the reference voltage line RL through the connection line 130.

Meanwhile, although not illustrated in FIG. 3, the corresponding data line DL can be connected to each of the plurality of subpixel circuits SPC. For example, the data line DL extending in the second direction Y and configured to provide the data voltage DATA for the red light can be connected to the first subpixel circuit SPC1. The data line DL extending in the second direction Y and configured to provide the data voltage DATA for the white light can be connected to the second subpixel circuit SPC2. The data line DL extending in the second direction Y and configured to provide the data voltage DATA for the blue light can be connected to the third subpixel circuit SPC3. The data line DL extending in the second direction Y and configured to provide the data voltage DATA for the green light can be connected to the fourth subpixel circuit SPC4.

In addition, although not illustrated in FIG. 3, the corresponding gate line GL can be connected to each of the plurality of subpixel circuits SPC. For example, the gate line GL extending in the first direction X and configured to provide the scan signal SCAN and/or the sensing signal SENSE can be connected to each of the plurality of subpixel circuits SPC. The subpixel circuits SPC disposed in the same pixel row are connected to the same gate line GL, such that the plurality of subpixel circuits SPC disposed in one pixel area PXA can be connected to the same gate line GL.

Meanwhile, as described with reference to FIG. 2, the plurality of repair areas LCA can be set on the reference voltage connection line 140 of each of the subpixel circuits SPC. The plurality of repair areas LCA can be disposed so as not to overlap the emission area EA of each of the plurality of subpixels SP. For example, the plurality of repair areas LCA can overlap non-emission areas of the plurality of subpixels SP.

A plurality of optical members 170 can be disposed in the plurality of repair areas LCA.

For example, the plurality of repair areas LCA can include a first repair area LCA1 adjacent to the first auxiliary portion connected to the first subpixel circuit SPC1 in the first main portion of the first reference voltage connection line 141, and a second repair area LCA2 adjacent to the second auxiliary portion connected to the second subpixel circuit SPC2 in the first main portion of the first reference voltage connection line 141. A first optical member 171 can be disposed to overlap the first repair area LCA1, and a second optical member 172 can be disposed to overlap the second repair area LCA2.

In addition, the plurality of repair areas LCA can further include a third repair area LCA3 adjacent to the third auxiliary portion connected to the third subpixel circuit SPC3 in the second main portion of the second reference voltage connection line 142, and a fourth repair area LCA4 adjacent to the fourth auxiliary portion connected to the fourth subpixel circuit SPC4 in the second main portion of the second reference voltage connection line 142. A third optical member 173 can be disposed to overlap the third repair area LCA3, and a fourth optical member 174 can be disposed to overlap the fourth repair area LCA4.

The plurality of members optical 170 can each concentrate the laser and provide the laser to the reference voltage connection line 140 disposed in the corresponding repair area LCA. Therefore, the reference voltage connection line 140 disposed in the corresponding repair area LCA can be cut.

The arrangements of the components included in the plurality of subpixels SP included in the display device 100 will be described in more detail with reference to FIG. 4. The display device 100 can include a first substrate 111, a buffer layer BF, a gate insulation layer GI, an interlayer insulation layer ILD, a passivation layer PAS, the reference voltage line RL, the driving transistor DT, the sensing transistor SET, the reference voltage connection line 140, a light-blocking layer LS, the data line DL, an overcoating layer OC, the light emitting diode ED, a bank 150, an encapsulation member 160, at least one color filter CF1 or CF2, an optical member 170, and a second substrate 112.

The first substrate 111 and the second substrate 112 can each include an insulating material. The first substrate 111 and the second substrate 112 can each include a transparent material. For example, the first substrate 111 and the second substrate 112 can each include glass or plastic.

The first substrate 111 can be disposed below the display device 100 and support the components of the display device 100. The second substrate 112 can be disposed above the display device 100 and protect the components of the display device 100. For example, the first substrate 111 and the second substrate 112 can be disposed to face each other, the first substrate 111 can be a lower substrate, and the second substrate 112 can be an upper substrate. However, the present disclosure is not limited thereto.

The light-blocking layer LS can be disposed on the first substrate 111. The light-blocking layer LS can be disposed to overlap the driving transistor DT, e.g., a first semiconductor layer ACT1 of the driving transistor DT. The light-blocking layer LS can serve to block external light entering the first semiconductor layer ACT1 in the area in which the driving transistor DT is formed.

The light-blocking layer LS can be configured as a single layer or multilayer made of any one of molybdenum (Mo), aluminum (Al), chromium (Cr), gold (Au), titanium (Ti), nickel (Ni), neodymium (Nd), and copper (Cu) or an alloy thereof. However, the present disclosure is not limited thereto.

The reference voltage connection line 140 and the reference voltage line RL can be disposed on the first substrate 111. The reference voltage connection line 140 and the reference voltage line RL can be disposed on the same layer as the light-blocking layer LS. For example, the reference voltage connection line 140 and the reference voltage line RL can be formed simultaneously by the same process and include the same material as the light-blocking layer LS. However, the present disclosure is not limited thereto.

The buffer layer BF can be disposed on the first substrate 111. For example, the buffer layer BF can be disposed on the first substrate 111 and cover the light-blocking layer LS, the reference voltage connection line 140, and the reference voltage line RL.

The buffer layer BF can protect the transistors from moisture penetrating into the first substrate 111 vulnerable to moisture penetration. The buffer layer BF can include an insulating material. For example, the buffer layer BF can be made of an inorganic insulating material such as silicon oxide (Siox) and silicon nitride (SiNx) or configured as a multilayer made of silicon oxide (SiOx) and silicon nitride (SiNx).

The semiconductor layers of the transistors can be disposed on the buffer layer BF. For example, the first semiconductor layer ACT1 of the driving transistor DT and a second semiconductor layer ACT2 of the sensing transistor SET can be disposed on the buffer layer BF. The first semiconductor layer ACT1 and the second semiconductor layer ACT2 can each be made of a silicon-based semiconductor material or an oxide-based semiconductor material. However, the present disclosure is not limited thereto.

The gate insulation layer GI can be disposed on the buffer layer BF. For example, the gate insulation layer GI can be disposed on the buffer layer BF and cover the first semiconductor layer ACT1 and the second semiconductor layer ACT2. The gate insulation layer GI can insulate the semiconductor layer and the gate electrode of the transistor. For example, the gate insulation layer GI can insulate the first semiconductor layer ACT1 and a first gate electrode GE1 of the driving transistor DT and insulate the second semiconductor layer ACT2 and a second gate electrode GE2 of the sensing transistor SET.

The gate insulation layer GI can include an insulating material. For example, the gate insulation layer GI can be made of an inorganic insulating material such as silicon oxide (Siox) and silicon nitride (SiNx) or configured as a multilayer made of silicon oxide (SiOx) and silicon nitride (SiNx). The gate insulation layer GI can include a material having high permittivity. For example, the gate insulation layer GI can include a high-K material such as hafnium oxide (HfO).

The gate electrodes of the transistors can be disposed on the gate insulation layer GI. For example, the first gate electrode GE1 of the driving transistor DT and the second gate electrode GE2 of the sensing transistor SET can be disposed on the gate insulation layer GI.

The gate electrode of each of the transistors can be disposed to overlap a channel area of the semiconductor layer of the corresponding transistor. For example, the first gate electrode GE1 of the driving transistor DT can overlap the channel area of the first semiconductor layer ACT1, and the second gate electrode GE2 of the sensing transistor SET can overlap the channel area of the second semiconductor layer ACT2.

The first gate electrode GE1 and the second gate electrode GE2 can each be configured as a single layer or multilayer made of any one of molybdenum (Mo), aluminum (Al), chromium (Cr), gold (Au), titanium (Ti), nickel (Ni), neodymium (Nd), and copper (Cu) or an alloy thereof. However, the present disclosure is not limited thereto.

Meanwhile, according to the embodiment, the gate line GL connected to each of the plurality of subpixels SP can be disposed on the same layer as the gate electrodes of the transistors, e.g., the first gate electrode GE1 and the second gate electrode GE2. For example, the gate line GL can be simultaneously formed by the same process and include the same material as the first gate electrode GE1 and the second gate electrode GE2. However, the present disclosure is not limited thereto.

With reference to FIG. 5, the connection line 130 can be further disposed on the gate insulation layer GI. The connection line 130 can be disposed on the same layer as the gate electrodes of the transistors, e.g., the first gate electrode GE1 and the second gate electrode GE2. For example, the connection line 130 can be simultaneously formed by the same process and include the same material as the first gate electrode GE1 and the second gate electrode GE2. However, the present disclosure is not limited thereto.

One end of the connection line 130 can be in contact with the reference voltage connection line 140 through the second contact hole CH2 formed through the gate insulation layer GI and the buffer layer BF. The other end of the connection line 130 can be in contact with the reference voltage line RL through the first contact hole CH1 formed through the gate insulation layer GI and the buffer layer BF. Therefore, the reference voltage connection line 140 can be provided with the reference voltage Vref from the reference voltage line RL through the connection line 130.

With reference back to FIG. 4, the interlayer insulation layer ILD can be disposed on the gate insulation layer GI. For example, the interlayer insulation layer ILD can be disposed on the gate insulation layer GI and cover the first gate electrode GE1, the second gate electrode GE2, and the connection line 130. The interlayer insulation layer ILD can insulate the gate electrode, the source electrode, and the drain electrode of the transistor. For example, the interlayer insulation layer ILD can insulate the first gate electrode GE1 of the driving transistor DT from a first source electrode SE1 and a first drain electrode DE1 and insulate the second gate electrode GE2 of the sensing transistor SET from a second source electrode SE2 and a second drain electrode DE2.

The interlayer insulation layer ILD can include an insulating material. For example, the interlayer insulation layer ILD can be made of an inorganic insulating material such as silicon oxide (SiOx) and silicon or configured as a multilayer made of silicon oxide (Siox) and silicon nitride (SiNx).

The source electrodes and the drain electrodes of the transistors can be disposed on the interlayer insulation layer ILD. For example, the first source electrode SE1 and the first drain electrode DE1 of the driving transistor DT and the second source electrode SE2 and the second drain electrode DE2 of the sensing transistor SET can be disposed on the interlayer insulation layer ILD.

The source electrodes and the drain electrodes of the transistors can be in contact with the gate electrodes of the corresponding transistors through contact holes formed through the interlayer insulation layer ILD and the gate insulation layer GI. For example, the first source electrode SE1 and the first drain electrode DE1 of the driving transistor DT can be connected to the first semiconductor layer ACT1 through a fourth contact hole CH4 and a fifth contact hole CH5 formed through the interlayer insulation layer ILD and the gate insulation layer GI. The second source electrode SE2 and the second drain electrode DE2 of the sensing transistor SET can be connected to the second semiconductor layer ACT2 through a sixth contact hole CH6 and a seventh contact hole CH7 formed through the interlayer insulation layer ILD and the gate insulation layer GI.

The first source electrode SE1, the second source electrode SE2, the first drain electrode DE1, and the second drain electrode DE2 can each be configured as a single layer or multilayer made of any one of molybdenum (Mo), aluminum (Al), chromium (Cr), gold (Au), titanium (Ti), nickel (Ni), neodymium (Nd), and copper (Cu) or an alloy thereof.

The data line DL can be disposed on the interlayer insulation layer ILD. For example, the data line DL can be disposed on the same layer as the first source electrode SE1, the second source electrode SE2, the first drain electrode DE1, and the second drain electrode DE2. For example, the data line DL can be simultaneously formed by the same process and include the same material as the first source electrode SE1, the second source electrode SE2, the first drain electrode DE1, and the second drain electrode DE2. However, the present disclosure is not limited thereto.

According to the embodiment, the high-potential power line VDDL and the low-potential power line VSSL connected to each of the plurality of subpixels SP can be disposed on the same layer as the source electrodes and the drain electrodes of the transistors, e.g., the first source electrode SE1, the second source electrode SE2, the first drain electrode DE1, and the second drain electrode DE2. For example, the high-potential power line VDDL and the low-potential power line VSSL can be simultaneously formed by the same process and include the same material as the first source electrode SE1, the second source electrode SE2, the first drain electrode DE1, and the second drain electrode DE2. However, the present disclosure is not limited thereto.

The passivation layer PAS can be disposed on the interlayer insulation layer ILD. For example, the passivation layer PAS can be disposed on the interlayer insulation layer ILD and cover the first source electrode SE1, the second source electrode SE2, the first drain electrode DE1, the second drain electrode DE2, and the data line DL.

The passivation layer PAS can suppress damage to the transistor caused by external moisture and impact. For example, the passivation layer PAS can extend along a surface of the transistor, e.g., a surface of the driving transistor DT and a surface of the sensing transistor SET.

The passivation layer PAS can include an insulating material. For example, the passivation layer PAS can be made of an inorganic insulating material such as silicon oxide (Siox) and silicon nitride (SiNx) or configured as a multilayer made of silicon oxide (SiOx) and silicon nitride (SiNx).

The overcoating layer OC can be disposed on the passivation layer PAS. The overcoating layer OC can include an insulating material. The overcoating layer OC can include a material different from the material of the passivation layer PAS. For example, the overcoating layer OC can include an organic insulating material. For example, the overcoating layer OC can include an organic material such as acrylic resin, epoxy resin, phenolic resin, polyamide resin, and polyimide resin.

The overcoating layer OC can remove a level difference caused by the transistor, e.g., the driving transistor DT and the sensing transistor SET, e.g., planarize the transistor, e.g., the driving transistor DT and the sensing transistor SET. For example, a top surface of the overcoating layer OC, which is opposite to the first substrate 111, can be a flat surface.

The light emitting diode ED can be disposed on the overcoating layer OC. For example, the light emitting diode ED can include a first electrode AND, a light-emitting layer EML, and a second electrode CAT disposed on the overcoating layer OC.

The first electrode AND can be disposed on the overcoating layer OC. The first electrode AND can be connected to the first source electrode SE1 or the first drain electrode DE1 of the driving transistor DT through a ninth contact hole CH9 formed through the overcoating layer OC and the passivation layer PAS. Therefore, the first electrode AND of the light emitting diode ED can be electrically connected to the driving transistor DT.

The first electrode AND can include an electrically conductive material. For example, the first electrode AND can include a material having high reflectance. For example, the first electrode AND can include metal such as aluminum (Al) and silver (Ag). The first electrode AND can have a multilayer structure. For example, the first electrode AND can have a structure in which a reflective electrode, which is made of metal, is positioned between transparent electrodes made of a transparent conductive material such as ITO and IZO. The first electrode AND can be an anode electrode of the light emitting diode ED.

The bank 150 can be disposed on the overcoating layer OC. The bank 150 can be formed to cover an edge of each of the first electrodes AND included in the plurality of subpixels SP and expose a part of each of the first electrodes AND. Therefore, the bank 150 can suppress a problem in which an electric current is concentrated at ends of the first electrode AND and luminous efficiency deteriorates.

The bank 150 can be disposed between the first electrodes AND included in the plurality of subpixels SP and expose at least a part of the first electrode AND, thereby defining the emission area EA of the subpixel SP. For example, the emission area EA of each of the plurality of subpixels SP, e.g., the first emission area EA1, the second emission area EA2, the third emission area EA3, and the fourth emission area EA4 can each define an area in which the first electrode AND, the light-emitting layer EML, and the second electrode CAT are sequentially stacked, and positive holes from the first electrode AND and electrons from the second electrode CAT are coupled to one another in the light-emitting layer EML to emit light. In this case, because an area in which the bank 150 is formed does not emit light, this area can be defined as a non-emission area NEA. An area, in which the bank 150 is not formed and the first electrode AND is exposed, can be defined as the emission area EA.

In addition, the bank 150 can be disposed between the first electrodes AND included in the plurality of subpixels SP and insulate the first electrodes AND disposed in the subpixels SP.

The bank 150 can be configured as an organic film made of acrylic resin, epoxy resin, phenolic resin, polyamide resin, and polyimide resin. However, the present disclosure is not limited thereto.

The light-emitting layer EML can be disposed on the first electrode AND. For example, the light-emitting layer EML can be disposed on the bank 150 and the first electrode AND exposed by the bank 150.

The light-emitting layer EML can create light with luminance corresponding to a voltage difference between the first electrode AND and the second electrode CAT. For example, the light-emitting layer EML can include an emission material layer (EML) including a light-emitting material. The light-emitting material can include an organic material, an inorganic material, or a hybrid material.

The light-emitting layer EML can have a multilayer structure. For example, the light-emitting layer EML can further include at least one of a hole injection layer (HIL), a hole transport layer (HTL), an electron transport layer (ETL), and an electron injection layer (EIL).

According to the embodiment, the light-emitting layer EML can be formed for each of the plurality of subpixels SP. For example, a red light-emitting layer configured to emit red light can be formed in the first subpixel SP1, a white light-emitting layer configured to emit white light can be formed in the second subpixel SP2, a blue light-emitting layer configured to emit blue light can be formed in the third subpixel SP3, and a green light-emitting layer configured to emit green light can be formed in the fourth subpixel SP4.

However, this is provided for illustrative purposes only, and the present disclosure is not limited thereto. The light-emitting layer EML can be a common layer formed in common in the plurality of subpixels SP. In this case, the light-emitting layer EML can be a white light-emitting layer configured to emit white light.

The second electrode CAT can be disposed on the light-emitting layer EML and the bank 150. The second electrode CAT can be disposed not only in the emission area EA but also in the non-emission area NEA. However, the present disclosure is not limited thereto.

The second electrode CAT can include an electrically conductive material. The second electrode CAT can include a material different from the material of the first electrode AND. A transmittance rate of the second electrode CAT can be higher than a transmittance rate of the first electrode AND. For example, the second electrode CAT can be configured as a transparent electrode made of a transparent conductive material such as ITO and IZO. Therefore, in the display device 100 according to the embodiment of the present disclosure, the light created by the light-emitting layer EML can be discharged through the second electrode CAT.

The second electrodes CAT included in the plurality of subpixels SP can be electrically connected to one another. For example, the second electrode CAT can be a common layer formed in common in the plurality of subpixels SP and supplied with the same voltage. The second electrode CAT can be a cathode electrode of the light emitting diode ED.

The encapsulation member 160 can be disposed on the light emitting diode ED. The encapsulation member 160 can be formed to cover the second electrode CAT. The encapsulation member 160 can suppress damage to the light emitting diode ED caused by moisture and impact from the outside. The encapsulation member 160 can have a multilayer structure. For example, the encapsulation member 160 can include at least one inorganic film and at least one organic film.

A color filter CF can be disposed on the encapsulation member 160. The color filter CF can be disposed on one surface, e.g., a bottom surface of the second substrate 112 that faces the first substrate 111. In this case, the first substrate 111, which has the encapsulation member 160, and the second substrate 112, which has the color filter CF, can be joined by a separate bonding layer. In this case, the bonding layer can be an optically clear resin layer (OCR) or an optically clear adhesive film (OCA). However, the present disclosure is not limited thereto.

The color filter CF can be patterned for each of the plurality of subpixels SP. For example, the color filter CF can include a first color filter CF1 disposed to correspond to the first emission area EA1 of the first subpixel SP1, a second color filter CF2 disposed to correspond to the second emission area EA2 of the second subpixel SP2, a third color filter disposed to correspond to the third emission area EA3 of the third subpixel SP3, and a fourth color filter disposed to correspond to the fourth emission area EA4 of the fourth subpixel SP4. For example, the first color filter CF1 can be a red color filter configured to transmit red light, the second color filter CF2 can be a white color filter configured to transmit white light, the third color filter can be a blue color filter configured to transmit blue light, and the fourth color filter can be a green color filter configured to transmit green light. Meanwhile, the second color filter CF2, which is the white color filter, can be made of a transparent organic material that transmits white light. However, the present disclosure is not limited thereto.

Meanwhile, the configuration has been described above in which the second color filter CF2, which is the white color filter, is disposed to correspond to the second emission area EA2 of the second subpixel SP2. However, this is provided for illustrative purposes only, and the present disclosure is not limited thereto. For example, the color filter may not be disposed to correspond to the second emission area EA2 of the second subpixel SP2.

According to the embodiment, the display device 100 can further include a black matrix disposed between the plurality of color filters CF. The black matrix can be provided between the plurality of subpixels SP and suppress the occurrence of a color mixture between the adjacent subpixels SP. Further, the black matrix can suppress reflection or a leak of light from lines disposed below the black matrix.

Meanwhile, as described above, some of the circuit elements provided in the plurality of subpixels SP can be defective. For example, in case that the driving transistor DT is defective, the light emitting diode ED, which is connected to the defective driving transistor DT may not emit light or can emit light with high luminance. For this reason, the defective subpixel can be visually recognized by a user.

In case that some of the plurality of subpixels SP are defective as described above, the reference voltage connection line 140 disposed in the repair area LCA of the display device 100 according to the embodiment of the present disclosure is cut by a laser L, and the reference voltage connection line 140 is electrically separated from the defective circuit element of the subpixel circuit SPC, such that the defective subpixel SP can be repaired.

Specifically, when the laser L emitted from above the display device 100 is provided to the reference voltage connection line 140 disposed in the repair area LCA, the reference voltage connection line 140 disposed in the corresponding repair area LCA can be cut. When the reference voltage connection line 140 disposed in the repair area LCA is cut by the laser L, the sensing transistor SET is electrically separated from the reference voltage line RL, such that the reference voltage Vref supplied from the reference voltage line RL is not applied to the subpixel circuit SPC, e.g., the sensing transistor SET of the corresponding subpixel SP. Therefore, because the reference voltage Vref is not supplied to the driving transistor DT from the sensing transistor SET, the driving transistor DT does not operate, and as a result, the light emitting diode ED does not emit light. As described above, the subpixel SP including a defective circuit element can become a dark spot by the repair process.

In order to perform the repair process using the laser L, the light-emitting layer EML does not need to be disposed on a propagation path of the laser L, and the light-emitting layer EML needs to be opened. For example, because the laser L needs to be emitted from the area that overlaps the non-emission area NEA, there can occur a problem in that the emission area EA decreases, i.e., an aperture ratio of the subpixel SP decreases to the extent of the area from which the laser L is emitted.

In order to suppress the decrease in aperture ratio, the display device 100 according to the embodiment of the present disclosure concentrates the laser L emitted to the repair area LCA by using the optical member 170 disposed on the bottom surface of the color filter CF while overlapping the non-emission area NEA, which can ensure the maximum aperture ratio of the emission area EA, i.e., the subpixel SP.

More specifically, the optical member 170 can be disposed to overlap the bank 150 disposed in the non-emission area NEA, and the optical member 170 can be disposed on the bottom surface of the color filter CF. For example, the optical member 170 can be disposed to overlap the repair area LCA positioned in the non-emission area NEA.

In addition, the optical member 170 can serve to concentrate the incident light. For example, the optical member 170 can include a Fresnel zone plate. In this case, the optical member 170 includes a plurality of closed-loop-shaped annular patterns. The light incident on the optical member 170 can be diffracted by the annular patterns, and the diffracted waves can constructively interfere, such that the light exiting the optical member 170 can be concentrated on a focal point of the optical member 170.

Therefore, as illustrated in FIG. 4, in case that the second subpixel SP is defective and a repair process is performed by cutting the repair area LCA of the reference voltage connection line 140 connected to the second subpixel SP, e.g., the second repair area LCA2 of the first reference voltage connection line 141 by emitting the laser L, the laser L, which enters the optical member 170, e.g., the second optical member 172 and exits the second optical member 172, can be concentrated by the second optical member 172 and then provided to the repair area LCA. In this case, because the concentrated laser L propagates to the repair area LCA, a width of a propagation path of the laser L in the first direction X and/or the second direction Y can be reduced, and the area of the propagation path of the laser L on the layer, on which the light-emitting layer EML is disposed on the propagation path of the laser L, can be minimized, such that a degree to which the light-emitting layer EML needs to be opened can be minimized. Therefore, the decrease in aperture ratio of the subpixel SP can be minimized.

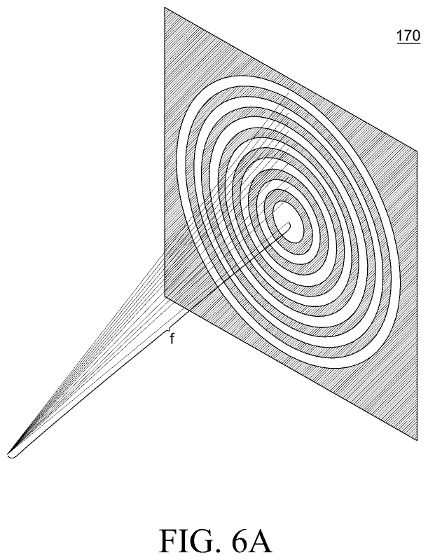

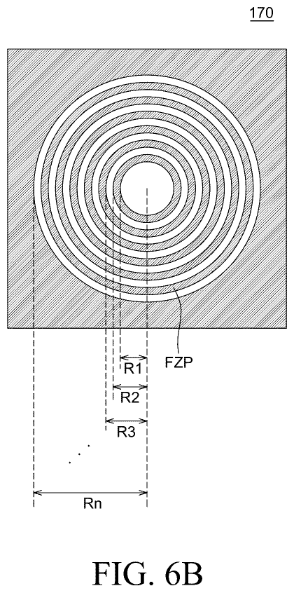

Meanwhile, as described above, the light entering the optical member 170 can be concentrated on the focal point of the optical member 170. To this end, a focal length of the optical member 170 can correspond to a distance from the optical member 170 to the reference voltage connection line 140 positioned in the repair area LCA. Hereinafter, the focal length of the optical member 170 will be described in detail with reference to FIGS. 6A and 6B.

FIGS. 6A and 6B are views for explaining an example of an optical member included in the display device in FIG. 3.

With reference to FIGS. 6A and 6B, the optical member 170, which includes the Fresnel zone plate as described above, can serve to concentrate the incident laser L. For example, the optical member 170 can include a plurality of closed-loop-shaped annular patterns, e.g., a plurality of closed annular patterns FZP disposed in concentrically circular shapes and spaced apart from one another. With the above-mentioned optical member 170, the incident laser L is diffracted by transparent areas that are areas spaced apart from one another between the plurality of closed annular patterns FZP formed in concentrically circular shapes and spaced apart from one another. Further, the diffracted waves constructively interfere, such that the laser L exiting the optical member 170 can be concentrated on the focal point of the optical member 170. As described above, when the laser L passes through the plurality of closed annular patterns FZP of the optical member 170, the laser L is diffracted between the plurality of closed annular patterns FZP and then discharged, such that the plurality of closed annular patterns FZP is not damaged by the laser L.

The plurality of closed annular patterns FZP included in the optical member 170 can be made of light-blocking metal. For example, the light-blocking metal can be configured as a single layer made of Cu, Mo, Al, Ag, and Ti or a combination thereof.

In this case, an opaque area, in which the plurality of closed annular patterns FZP is disposed, and a transparent area, in which the closed annular pattern FZP is not disposed, are formed on the optical member 170. The diffraction of the incident laser L occurs for each boundary between the opaque area and the transparent area, such that the corresponding laser L can be concentrated on the focal point of the optical member 170.

In this case, among distances R1, R2, R3, and. . . . Rn from the center point of the optical member 170 to the boundaries between the opaque area and the transparent area, a distance Rn to an n-th (here, n is a natural number) boundary can be calculated on the basis of Equation 1 below.

$$Rn = \sqrt{n λ f + \frac{{n}^{2} {λ}^{2}}{4}} \qquad [ Equation 1 ]$$

In Equation 1, Rn represents the distance Rn to the n-th boundary among the distances R1, R2, R3, and. . . . Rn from the center point of the optical member 170 to the boundaries between the opaque area and the transparent area, A represents a wavelength of the laser L, and f represents a focal length f of the optical member 170.

As described above, it is possible to design the focal length f of the optical member 170 by adjusting the widths of the plurality of closed annular patterns FZP included in the optical member 170 and adjusting intervals between the plurality of closed annular patterns FZP. For example, as described with reference to FIG. 5, in case that the focal length f of the optical member 170 is designed on the basis of a distance from a point, at which the optical member 170 is disposed, to the reference voltage connection line 140 disposed in the repair area LCA, the laser L entering the optical member 170 can be concentrated during the process of repairing the defective subpixel, and the concentrated laser L can be provided to the reference voltage connection line 140 disposed in the repair area LCA.

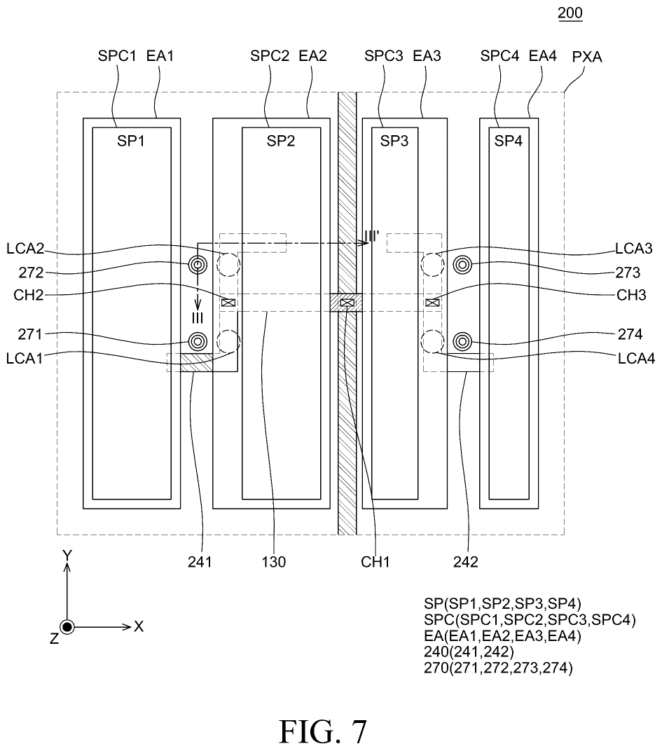

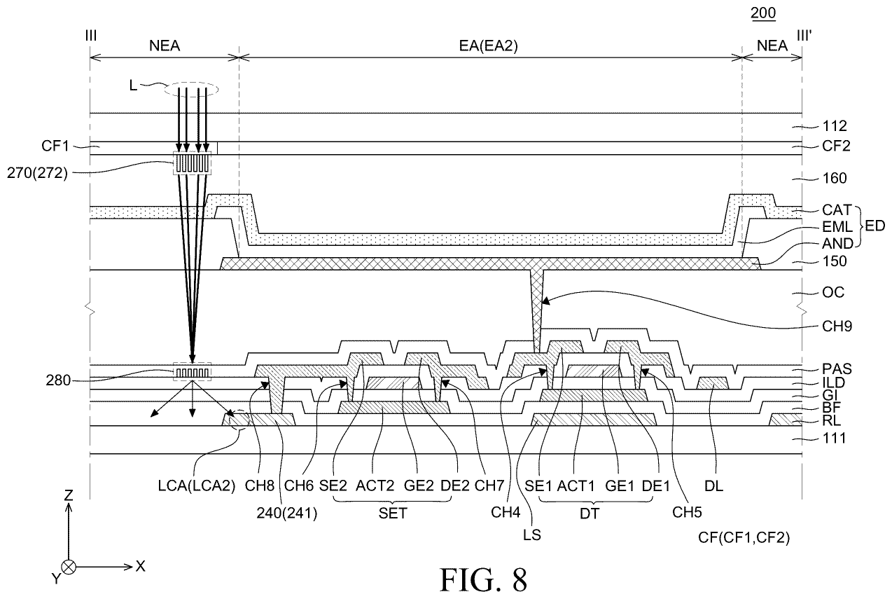

FIG. 7 is an enlarged top plan view of a display device according to another embodiment of the present disclosure. FIG. 8 is a cross-sectional view illustrating an example cut along line III-III′ in FIG. 7.

Particularly, FIGS. 7 and 8 illustrate embodiments related to a grating member 280 and modified from the embodiments in FIGS. 3 and 4. Therefore, with reference to FIGS. 7 and 8, the description will be focused on differences from the embodiments in FIGS. 3 and 4 to avoid a repeated description. In this regard, FIG. 8 illustrates an example of a cross-sectional structure of a display device 200 according to another embodiment of the present disclosure.

With reference to FIG. 7, the display device 200 according to another embodiment of the present disclosure can include the plurality of subpixels SP disposed in one pixel area PXA and each including the corresponding subpixel circuit SPC.

A reference voltage connection line 240 disposed between the plurality of subpixels SP can be connected to the connection line 130 disposed to traverse the corresponding pixel area PXA in the first direction X. For example, the reference voltage connection line 240 can include a first reference voltage connection line 241 disposed to overlap the second emission area EA2 of the second subpixel SP2, and a second reference voltage connection line 242 disposed to overlap the third emission area EA3 of the third subpixel SP3.

The first reference voltage connection line 241 can include a first main portion extending in the second direction Y and disposed to at least overlap the second emission area EA2. The first main portion of the first reference voltage connection line 241 and the connection line 130 can be connected through the second contact hole CH2 in the central portion of the first main portion of the first reference voltage connection line 241. In addition, the first reference voltage connection line 241 can include a first auxiliary portion extending from one end of the first main portion in a direction opposite to the first direction X and connected to the first subpixel circuit SPC1, and a second auxiliary portion extending from the other end of the first main portion in the first direction X and connected to the second subpixel circuit SPC2. Therefore, the reference voltage Vref can be supplied to the first subpixel circuit SPC1 and the second subpixel circuit SPC2 through the first reference voltage connection line 241 connected to the reference voltage line RL through the connection line 130.

The second reference voltage connection line 242 can include a second main portion extending in the second direction Y and disposed to at least overlap the third emission area EA3. The second main portion of the second reference voltage connection line 242 and the connection line 130 can be connected through the third contact hole CH3 in the central portion of the second main portion of the second reference voltage connection line 242. In addition, the second reference voltage connection line 242 can include a third auxiliary portion extending from one end of the second main portion in a direction opposite to the first direction X and connected to the third subpixel circuit SPC3, and a fourth auxiliary portion extending from the other end of the second main portion in the first direction X and connected to the fourth subpixel circuit SPC4. Therefore, the reference voltage Vref can be supplied to the third subpixel circuit SPC3 and the fourth subpixel circuit SPC4 through the second reference voltage connection line 242 connected to the reference voltage line RL through the connection line 130.

Meanwhile, the plurality of repair areas LCA can be set on the reference voltage connection line 240 of each of the subpixel circuits SPC. In this case, because the reference voltage connection line 240 is disposed to at least partially overlap the emission area EA, the plurality of repair areas LCA can be disposed to overlap the emission areas EA of the plurality of subpixels SP. For example, the plurality of repair areas LCA can include the first repair area LCA1 configured to overlap the second emission area EA2 and disposed adjacent to the first auxiliary portion connected to the first subpixel circuit SPC1 in the first main portion of the first reference voltage connection line 241, and the second repair area LCA2 configured to overlap the second emission area EA2 and disposed adjacent to the second auxiliary portion connected to the second subpixel circuit SPC2 in the first main portion of the first reference voltage connection line 241. In addition, the plurality of repair areas LCA can include the third repair area LCA3 configured to overlap the third emission area EA3 and disposed adjacent to the third auxiliary portion connected to the third subpixel circuit SPC3 in the second main portion of the second reference voltage connection line 242, and the fourth repair area LCA4 configured to overlap the third emission area EA3 and disposed adjacent to the fourth auxiliary portion connected to the fourth subpixel circuit SPC4 in the second main portion of the second reference voltage connection line 242.

In addition, a plurality of optical members 270 can be disposed in the non-emission area NEA of the corresponding pixel area PXA. For example, the plurality of optical members 270 can be disposed between the plurality of subpixels SP. Therefore, the area, in which the optical member 270 is disposed, does not overlap the repair area LCA.

Specifically, the plurality of optical members 270 can include a first optical member 271 disposed between the first subpixel SP1 and the second subpixel SP2 and disposed at one side of the first repair area LCA1 based on the first direction X, a second optical member 272 disposed between the first subpixel SP1 and the second subpixel SP2 and disposed at one side of the second repair area LCA2 based on the first direction X, a third optical member 273 disposed between the third subpixel SP3 and the fourth subpixel SP4 and disposed at one side of the third repair area LCA3 based on the first direction X, and a fourth optical member 274 disposed between the third subpixel SP3 and the fourth subpixel SP4 and disposed at one side of the fourth repair area LCA4 based on the first direction X.

The plurality of optical members 270 can serve to concentrate the laser L. In this case, because the area, in which the optical member 270 is disposed, and the repair area LCA do not overlap each other as described above, the laser L can be provided to an area different from the repair area LCA in case that the laser L concentrated while passing through the optical member 270 is provided to a line, which is a repair target, in an intact manner.

Therefore, the display device 200 according to another embodiment of the present disclosure can further include the grating member disposed to overlap the plurality of optical members 270 and configured to diffuse the laser L provided from the plurality of optical members 270.

With reference to FIG. 8 together for a detailed description of the above-mentioned configuration, the grating member 280 can be disposed on the interlayer insulation layer ILD. In addition, the grating member 280 can be disposed in the non-emission area NEA. For example, the grating member 280 can be disposed on the interlayer insulation layer ILD and overlap the optical member 270.

However, the arrangement of the grating member 280 is not limited thereto. The grating member 280 can be disposed above any one of the passivation layer PAS, the gate insulation layer GI, and the buffer layer BF instead of the interlayer insulation layer ILD and overlap the optical member 270.

The grating member 280 can include a metallic material. For example, the grating member 280 can be configured as a single layer or multilayer made of any one of molybdenum (Mo), aluminum (Al), chromium (Cr), gold (Au), titanium (Ti), nickel (Ni), neodymium (Nd), and copper (Cu) or an alloy thereof. According to the embodiment, the grating member 280 can be simultaneously formed by the same process and include the same material as at least one of the first source electrode SE1, the second source electrode SE2, the first drain electrode DE1, and the second drain electrode DE2 disposed on the same layer. However, the present disclosure is not limited thereto.

The grating member 280 can serve to diffuse the laser L provided from the optical member 270. For example, the grating member 280 can include a diffraction grating. In this case, the laser L entering the grating member 280 has a diffraction effect. Parts of the laser L passing through the diffraction grating included in the grating member 280 interfere with one another while being diffracted, such that the laser L having passed through the grating member 280 can be diffused and provided.

In this case, as described above, because the area irradiated with the laser L, i.e., the area, in which the optical member 270 is disposed, does not overlap the repair area LCA, the laser L discharged from the optical member 270 and then concentrated is diffused by the grating member 280 and provided. Therefore, at least a part of the diffused laser L can be provided to the reference voltage connection line 240 disposed in the repair area LCA. Therefore, the reference voltage connection line 240 disposed in the repair area LCA can be cut.

In this case, because the grating member 280 for diffusing the laser L is positioned below the light emitting diode ED, the laser L exiting the optical member 270 is concentrated while propagating toward the grating member 280 even though the light entering the grating member 280 is diffused and discharged, the grating member 280 does not affect a size and an area of the light-emitting layer EML. Therefore, the maximum aperture ratio of the emission area EA, i.e., the subpixel SP can be ensured.

Meanwhile, the optical member 270 can be designed by setting the focal length f as the point at which the laser L exiting the optical member 270 is concentrated and the grating member 280 is positioned. For example, as described with reference to FIGS. 6A and 6B, it is possible to design the focal length f of the optical member 270 by adjusting the widths of the plurality of closed annular patterns FZP included in the optical member 270 and adjusting the intervals between the plurality of closed annular patterns FZP. However, this is provided for illustrative purposes only. The focal length f of the optical member 270 can be variously designed.

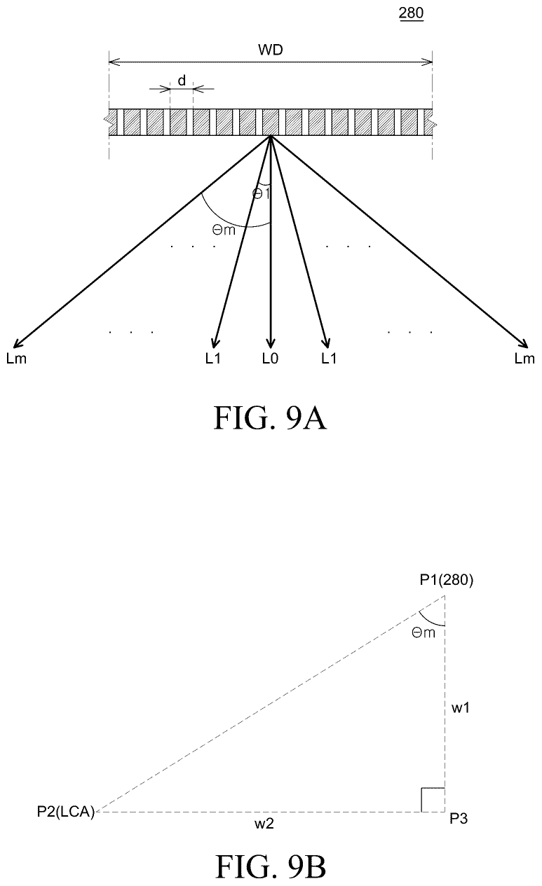

Meanwhile, as described above, the laser L entering the grating member 280 is diffracted and diffused by the diffraction grating included in the grating member 280. A degree of diffusion, e.g., an angle of the laser L diffused from the grating member 280 can be determined on the basis of a horizontal distance between the area, in which the grating member 280 is disposed, and the repair area LCA. This configuration will be described in detail with reference to FIGS. 9A and 9B.

FIGS. 9A and 9B are views for explaining an example of the grating member included in the display device in FIG. 7.

With reference to FIGS. 9A and 9B, the grating member 280 can include a plurality of diffraction gratings and diffracts and diffuses the incident laser L. For example, the incident laser L can be diffracted m times (here, m is a natural number) by the grating member 280 and diffused. Therefore, the laser L entering the grating member 280 can be distributed as a 0th the laser L0 that propagates along a path substantially identical to the path of the incident laser L without being diffracted and diffused by the grating member 280, a first laser L1 that is diffracted once by the grating member 280 and diffused at a first angle θ1, . . . , and an m-th laser Lm that is diffracted m times by the grating member 280 and diffused at an m-th angle θm.

In this case, the repair area LCA is designed to be positioned on the optical path of the corresponding laser by using the laser beams diffracted and diffused by the grating member 280, e.g., the first laser L1, which is diffracted once and diffused, . . . , the m-th laser Lm, which is diffracted m times and diffused, except for the 0th the laser L0 that is not diffracted and diffused, such that the line disposed in the repair area LCA can be cut.

For example, the m-th angle θm, which is a diffusion angle of the m-th laser Lm diffracted m times and diffused, can be calculated on the basis of Equation 2 below.

mλ=d sin 0m [Equation 2]

In Equation 2, λ represents a wavelength of the laser L, d represents a spacing distance d between the plurality of diffraction gratings included in the grating member 280 and spaced apart from one another, and Om represents the m-th angle θm that is the diffusion angle of the m-th laser Lm.

In addition, with reference to FIG. 9B, assuming that a right-angled triangular has a first point P1 corresponding to a center point of the grating member 280, a second point P2 corresponding to the repair area LCA, a line segment, i.e., a hypotenuse connecting the first point P1 and the second point P2, and a third point P3, the grating member 280 can be disposed in the interlayer insulation layer ILD, and the m-th angle θm, which is the diffusion angle of the m-th laser Lm, can be determined on the basis of a vertical distance between the first point P1, at which the grating member 280 is disposed, and the second point P2, at which the repair area LCA is disposed, i.e., a first distance w1 between the first point P1 and the third point P3, and a horizontal distance between the first point P1, at which the grating member 280 is disposed, and the second point P2, at which the repair area LCA is disposed, i.e., a second distance w2 between the second point P2 and the third point P3. The m-th angle θm can be designed by adjusting the spacing distance d between the plurality of diffraction gratings included in the grating member 280 and adjusting the wavelength of the laser L to design the diffusion angle as the m-th angle θm determined on the basis of the first distance w1 and the second distance w2.

As illustrated in FIG. 9B, as the first distance w1 between the first point P1 and the third point P3, i.e., the vertical distance between the grating member 280 and the repair area LCA increases, the horizontal distance between the grating member 280 and the repair area LCA, e.g., the second distance w2 between the second point P2 and the third point P3 can be sufficiently ensured even though the diffusion angle remains the same. To this end, according to the embodiment, a thickness of the insulation layer, e.g., at least one of the buffer layer BF, the gate insulation layer GI, and the interlayer insulation layer ILD disposed between the grating member 280 and the reference voltage connection line 240 disposed in the repair area LCA can be adjusted, and/or at least one of the buffer layer BF, the gate insulation layer GI, and the interlayer insulation layer ILD can be formed as a multilayer.

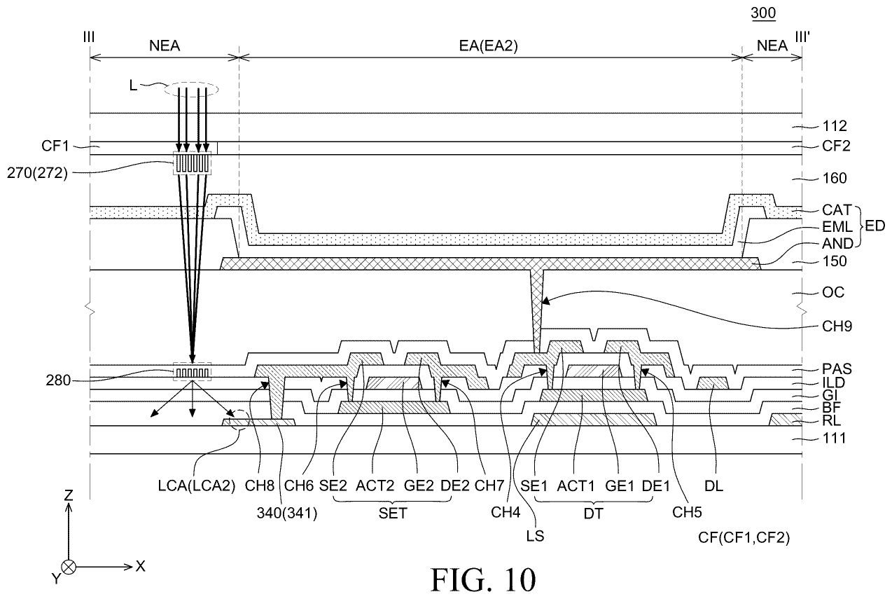

FIG. 10 is a cross-sectional view illustrating another example cut along line III-III′ in FIG. 7.

Particularly, FIG. 10 illustrates an embodiment related to a reference voltage connection line 340 and modified from the embodiment in FIG. 8. Therefore, with reference to FIG. 10, the description will be focused on differences from the embodiment in FIG. 8 to avoid a repeated description.

In this regard, FIG. 10 illustrates an example of a cross-sectional structure of a display device 300 according to still another embodiment of the present disclosure.

With reference to FIG. 10, the display device 300 according to still another embodiment of the present disclosure can include the plurality of subpixels SP disposed in one pixel area PXA and each including the corresponding subpixel circuit SPC.

As described above, the reference voltage connection line 340, the light-blocking layer LS, and the reference voltage line RL disposed on the first substrate 111 can be disposed on the same layer.

In this case, the reference voltage connection line 340, which is disposed in the repair area LCA and is to be cut by the laser L when the repair process is performed on the corresponding subpixel SP determined as a defective subpixel, can be formed by a halftone mask process. Therefore, in comparison with the light-blocking layer LS and the reference voltage line RL disposed on the same layer, a height of the reference voltage connection line 340 can be lower than a height of the light-blocking layer LS and a height of the reference voltage line RL. Therefore, the reference voltage connection line 340 disposed in the repair area LCA can be more easily cut by the laser L during the repair process.

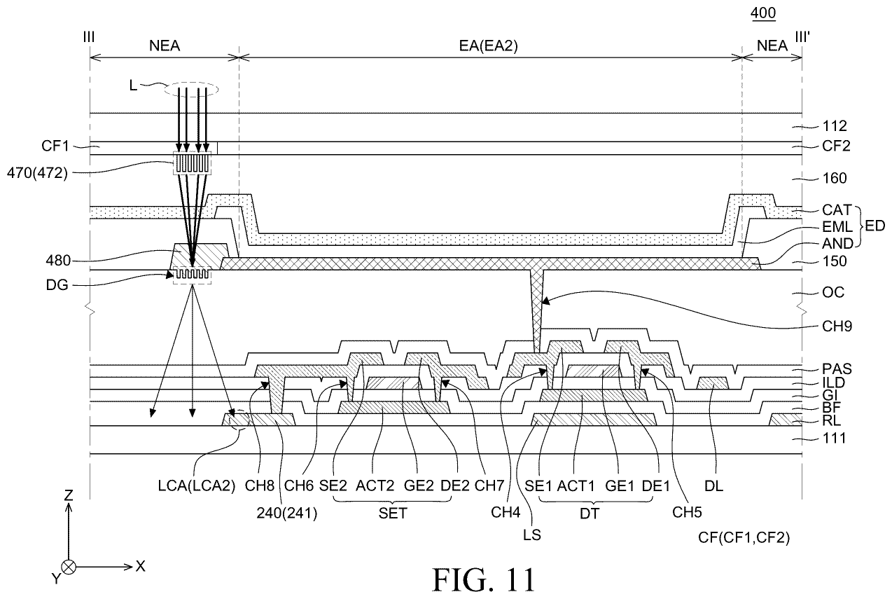

FIG. 11 is a cross-sectional view illustrating still another example cut along line III-III′ in FIG. 7.

Particularly, FIG. 11 illustrates an embodiment related to a grating member 480 and modified from the embodiment in FIG. 8. Therefore, with reference to FIG. 11, the description will be focused on differences from the embodiment in FIG. 8 to avoid a repeated description.

In this regard, FIG. 11 illustrates an example of a cross-sectional structure of a display device 400 according to yet another embodiment of the present disclosure.

With reference to FIG. 11, the display device 400 according to still another embodiment of the present disclosure can include the plurality of subpixels SP disposed in one pixel area PXA and each including the corresponding subpixel circuit SPC. The plurality of subpixels SP can each include a grating pattern DG formed on the overcoating layer OC, and the grating member 480 disposed to correspond to the grating pattern DG.

The overcoating layer OC can include the grating pattern DG formed in at least a partial area. For example, the grating pattern DG can be formed by patterning a top surface of the overcoating layer OC that overlaps the non-emission area NEA, e.g., the area in which an optical member 270 is disposed. For example, the grating pattern DG can be formed by patterning the top surface of the overcoating layer OC in a portion corresponding to an interface between the overcoating layer OC and the bank 150.

The grating member 480 can be disposed on the overcoating layer OC. In addition, the grating member 480 can be disposed in the non-emission area NEA. For example, the grating member 480 can be disposed above the grating pattern DG of the overcoating layer OC. In this case, at least a part of the grating member 480 can fill a space patterned by the grating pattern DG of the overcoating layer OC.

The grating member 480 can include an insulating material. For example, the grating member 480 can include an insulating material different in refractive index from the overcoating layer OC.

In this case, the laser L provided from the optical member 470 by the shape of the grating pattern DG can be diffused by the grating member 480 by the difference in refractive index between the grating member 480 and the overcoating layer OC. For example, the grating pattern DG of the overcoating layer OC and the grating member 480, which fills the space patterned by the grating pattern DG, can serve as diffraction gratings, such that the laser L having passed through the grating member 480 can be diffused and provided.

Meanwhile, the optical member 470 can be designed by setting the focal length f as the point at which the laser L exiting the optical member 470 is concentrated and the grating member 480 is positioned. For example, as described with reference to FIGS. 6A and 6B, it is possible to design the focal length f of the optical member 470 by adjusting the widths of the plurality of closed annular patterns FZP included in the optical member 470 and adjusting the intervals between the plurality of closed annular patterns FZP. However, this is provided for illustrative purposes only. The focal length f of the optical member 470 can be variously designed.

In addition, the diffusion angle can be designed so that the diffracted and diffused from the grating member 480 reaches the reference voltage connection line 240 disposed in the repair area LCA. For example, as described with reference to FIGS. 9A and 9B, the diffusion angle can be designed by adjusting the spacing distance d between the plurality of diffraction gratings included in the grating member 480 and spaced apart from one another, e.g., the spacing distance between the grating patterns DG of the overcoating layer OC.

In addition, the grating member 480 can be formed to cover edges of the first electrodes AND included in the plurality of subpixels SP and formed to be higher than a height of the first electrode AND. Therefore, it is possible to inhibit the first electrodes AND, which are included in the adjacent subpixels SP, from being electrically connected to one another.

In addition, a residual film for forming the first electrode AND can be formed in an area between the first electrodes AND included in the adjacent subpixels SP, e.g., the non-emission area NEA when the first electrode AND is formed. In case that the patterning process is performed to form the grating pattern DG on the overcoating layer OC, the grating pattern DG and the residual film of the first electrode AND can inhibit the first electrodes AND included in the adjacent subpixels SP from being electrically connected.

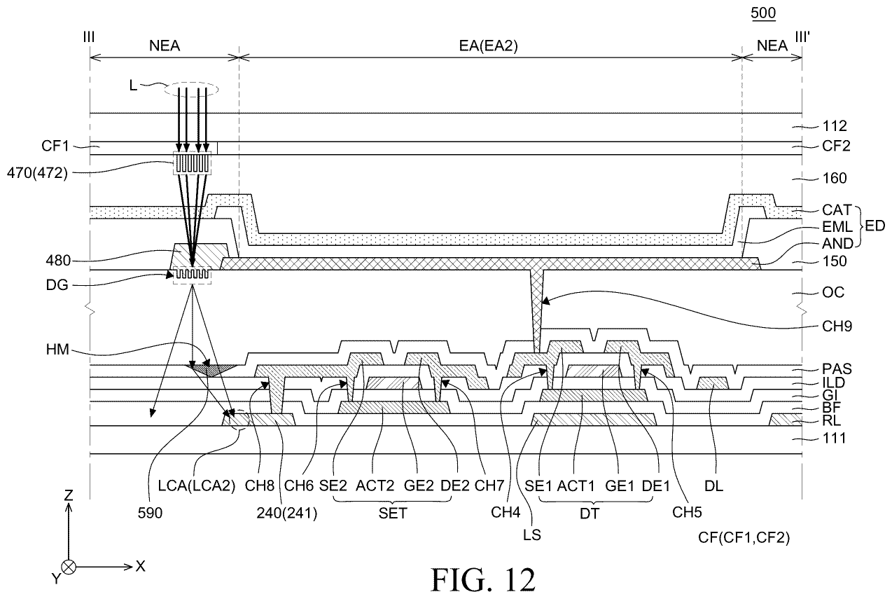

FIG. 12 is a cross-sectional view illustrating yet another example cut along line III-III′ in FIG. 7.

Particularly, FIG. 12 illustrates an embodiment related to a refraction member 590 and modified from the embodiment in FIG. 11. Therefore, with reference to FIG. 12, the description will be focused on differences from the embodiment in FIG. 11 to avoid a repeated description.

In this regard, FIG. 12 illustrates an example of a cross-sectional structure of a display device 500 according to still yet another embodiment of the present disclosure.

With reference to FIG. 12, the display device 500 according to still another embodiment of the present disclosure can include the plurality of subpixels SP disposed in one pixel area PXA and each including the corresponding subpixel circuit SPC. The plurality of subpixels SP can each include the refraction member 590 disposed on the passivation layer PAS.

The passivation layer PAS can include a groove HM formed in at least a partial area thereof. For example, the groove HM can be formed by patterning a top surface of the passivation layer PAS that overlaps the non-emission area NEA, e.g., at least a part of the area in which the grating member 480 is disposed in the passivation layer PAS. For example, the groove HM formed by patterning the top surface of the passivation layer PAS can have a triangular pyramidal shape. Therefore, in a plan view, the groove HM formed by patterning the top surface of the passivation layer PAS can have a triangular shape, as illustrated in FIG. 12.

The refraction member 590 can be disposed on the passivation layer PAS. In addition, the refraction member 590 can be disposed on the non-emission area NEA. For example, the refraction member 590 can be disposed to fill the patterned groove HM of the passivation layer PAS. Therefore, the refraction member 590 can have a triangular pyramidal shape. Therefore, in a plan view, the refraction member 590 can have a triangular shape, as illustrated in FIG. 12.

The refraction member 590 can include an insulating material. For example, the refraction member 590 can include an insulating material having a refractive index higher than a refractive index of the passivation layer PAS.

Therefore, due to the difference in the refractive index between the refraction member 590 and the passivation layer PAS, the laser, which propagates along a path substantially identical to the path of the laser L entering the grating member 480 without being diffracted and diffused among the parts of the laser L exiting the grating member 480 can be refracted in optical path by the refraction member 590 can propagate to the repair area LCA. For example, the laser L, which propagates in a direction parallel to the third direction Z instead of a direction toward the repair area LCA like the 0th the laser L0 in FIG. 9A, can be refracted in optical path by the refraction member 590 can propagate to the repair area LCA.

Therefore, not only the laser L, which is diffracted and diffused by the grating member 480, but also the laser L, which is not diffracted and diffused, is refracted by the refraction member 590 and provided to the reference voltage connection line 240 disposed in the repair area LCA. Therefore, the reference voltage connection line 240 disposed in the repair area LCA can be more easily cut during the repair process.

The example embodiments of the present disclosure can also be described as follows:

According to an aspect of the present disclosure, there is provided a display device. The display device can comprises a substrate comprising a emission area and a non-emission area, at least one transistor disposed on the substrate and disposed to overlap the emission area, a line disposed on the substrate and connected to the at least one transistor, at least one light emitting diode disposed on the at least one transistor and comprising a first electrode, a light-emitting layer, and a second electrode, and an optical member disposed on the at least one light emitting diode and disposed to overlap the non-emission area.

The line can comprise a repair area, and the optical member is disposed to overlap the repair area.

A laser entering the optical member can be concentrated and provided to the repair area of the line.

The optical member can comprise a plurality of closed annular patterns each having a closed-loop shape and including a metallic material.

The display device can further comprise a color filter disposed on the at least one light emitting diode, wherein the optical member is disposed on a bottom surface of the color filter.

The line can comprise at least one of a reference voltage connection line connected to the at least one transistor and configured to provide a reference voltage, a data line configured to provide a data voltage, a high-potential power line configured to provide a high-potential power voltage, and a low-potential power line configured to provide a low-potential power voltage.

The line comprises a repair area, and the optical member is disposed so as not to overlap the repair area.

The display device can further comprise a grating member disposed between the line and the optical member.

The grating member can be disposed to overlap the optical member.

The grating member can be positioned below the at least one light emitting diode.

The grating member can include a metallic material.

The grating member can be disposed on the same layer as the first electrode of the at least one light emitting diode.

The display device can further comprise an overcoating layer disposed between the at least one transistor and the at least one light emitting diode, wherein the overcoating layer comprises a grating pattern at least partially patterned.

The grating member can be disposed on the overcoating layer and formed to fill a space patterned by the grating pattern of the overcoating layer.

A height of the grating member can be higher than a height of the first electrode.

The grating member can comprise an insulating material different in refractive index from the overcoating layer.

The display device can further comprise a refraction member disposed between the line and the grating member.

The refraction member includes an insulating material.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto.

Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device comprising:
a substrate comprising an emission area and a non-emission area;
at least one transistor disposed on the substrate and overlapping the emission area;
a line disposed on the substrate and connected to the at least one transistor;
at least one light emitting diode disposed on the at least one transistor and comprising a first electrode, a light-emitting layer, and a second electrode; and
an optical member disposed on the at least one light emitting diode and overlapping the non-emission area.

2. The display device of claim 1, wherein the line comprises a repair area, and the optical member overlaps the repair area.

3. The display device of claim 2, wherein a laser entering the optical member is provided and concentrated on the repair area of the line.

4. The display device of claim 1, wherein the optical member comprises a plurality of closed annular patterns each having a closed-loop shape and including a metallic material.

5. The display device of claim 4, wherein in the optical member, areas in which the plurality of closed annular patterns are disposed concentrically are opaque and areas that are spaced apart from one another between the plurality of closed annular patterns are transparent.

6. The display device of claim 1, further comprising:
a color filter disposed on the at least one light emitting diode,
wherein the optical member is disposed on a bottom surface of the color filter.

7. The display device of claim 1, wherein the line comprises at least one of:
a reference voltage connection line connected to the at least one transistor and configured to provide a reference voltage,
a data line configured to provide a data voltage,
a high-potential power line configured to provide a high-potential power voltage, and
a low-potential power line configured to provide a low-potential power voltage.

8. The display device of claim 1, wherein the line comprises a repair area, and the optical member is disposed so as not to overlap the repair area.

9. The display device of claim 8, further comprising:
a grating member disposed between the line and the optical member.

10. The display device of claim 9, wherein the grating member is disposed to overlap the optical member.

11. The display device of claim 9, wherein the grating member is positioned below the at least one light emitting diode.

12. The display device of claim 11, wherein the grating member includes a metallic material.

13. The display device of claim 9, wherein the grating member is disposed on a same layer as the first electrode of the at least one light emitting diode.

14. The display device of claim 13, further comprising:
an overcoating layer disposed between the at least one transistor and the at least one light emitting diode,
wherein the overcoating layer comprises a grating pattern that is at least partially patterned.

15. The display device of claim 14, wherein the grating member is disposed on the overcoating layer and filling a space patterned by the grating pattern of the overcoating layer.

16. The display device of claim 13, wherein a height of the grating member is higher than a height of the first electrode.

17. The display device of claim 14, wherein the grating member comprises an insulating material having a different refractive index from the overcoating layer.

18. The display device of claim 13, further comprising:
a refraction member disposed between the line and the grating member.

19. The display device of claim 18, wherein the refraction member includes an insulating material.

20. The display device of claim 1, wherein the optical member includes a Fresnel zone plate.
